(19) United States
(12) Patent Application Publication
(10) Pub. No.: US 2005/0064705 A1
(43) Pub. Date: Mar. 24, 2005

(54) Method for producing thin metal-containing layers having a low electrical resistance

(76) Inventor: Hans-Joachim Barth, Lutzowstr (DE)

Correspondence Address: BRINKS HOFER GILSON & LIONE;INFINEON, PO BOX 10395, CHICAGO, IL, 60610, US

(21) Appl. No.: 10/495,110

(22) PCT Filed: Sep. 9, 2002
(86) PCT No.: PCT/DE02/03344

(30) Foreign Application Priority Data
Nov. 7, 2001 (DE) 101-54-500.2

(51) Int. Cl. H01L 21/44

(52) U.S. Cl. 438/658; 438/660

(57) ABSTRACT

The invention relates to a process for producing metal-containing thin films with a low electrical resistance, in which first of all a metal-containing layer (5′) with a first grain size is formed up to a recrystallization thickness (d1), and then, at this recrystallization thickness (d1), a recrystallization is carried out in order to produce a metal-containing layer (5″) with a larger grain size. Finally, the metal-containing layer (5″) with the larger grain size is thinned to a desired target thickness (d2), resulting in a very thin metal-containing layer with an electrical resistance which is reduced further.

The present invention relates to a process for producing metal-containing thin films with a low electrical resistance, and in particular to thin Cu interconnects for use in semiconductor components.

Hitherto, the fabrication of integrated semiconductor circuits has preferably involved depositing and structuring layers of aluminium in wiring levels to produce interconnects, an Al layer in principle being deposited to a predetermined target thickness and then structured by means of conventional photolithographic and associated etching processes.

Increasingly, however, alternative materials are being employed in particular for use in metallization layers of this type in order to achieve the increasing integration density. The use of copper, for example, for wiring levels of this type has made it possible to develop integrated circuits which operate at much higher speeds and with a lower power consumption, on account of the significantly lower resistances compared to aluminium. However, a drawback of using alternative materials of this type, in particular copper, is the relative difficulty of handling the material which results, for example, from deposition and/or etching problems.

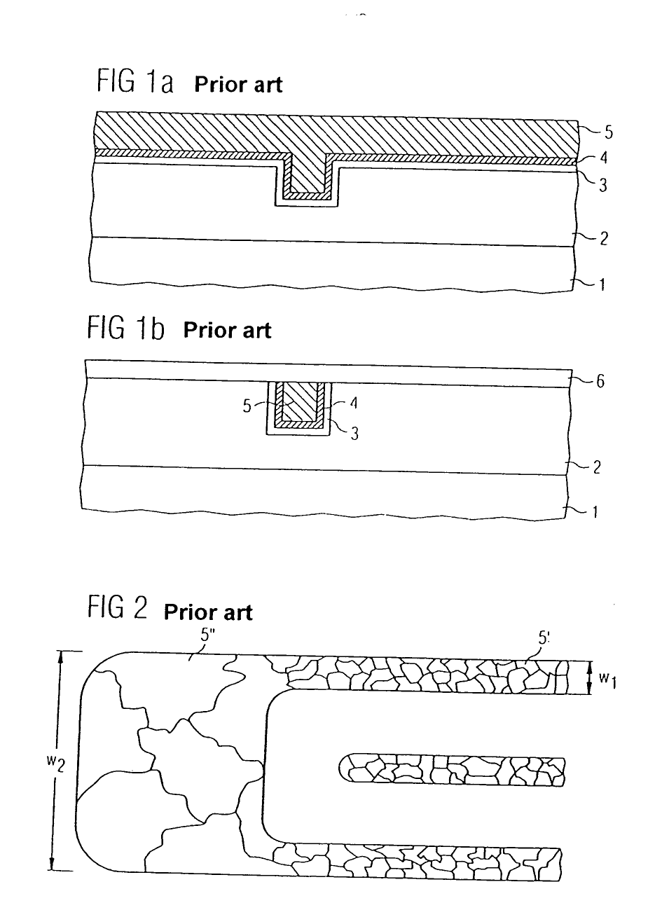

To eliminate these problems, by way of example the Damascene technology illustrated in FIGS. 1a and 1b has been developed.

FIGS. 1a and 1b show simplified sectional illustrations demonstrating significant production steps involved in a conventional process of this type for forming metal-containing thin films.

In accordance with FIG. 1a, a dielectric layer 2 is deposited on a substrate material 1 which, for example, represents an integrated semiconductor circuit in a semiconductor substrate with elemental layers above it, and a trench is formed in the dielectric layer for the interconnect which is subsequently to be formed. In subsequent steps, a diffusion barrier layer 3 and a seed layer 4 are formed both on the surface and in the trench of the dielectric layer 2, allowing or simplifying subsequent growth of a Cu layer 5.

Then, in accordance with FIG. 1b, a CMP (chemical mechanical polishing process) is used to remove the layer sequence which remains above the trench and to form a further diffusion barrier layer 6 as a so-called cap layer.

In this way, it is possible to produce even very finely structured interconnects using materials which are difficult to handle. However, a drawback of this process is that there is a significant deterioration in the electrical conductivity, in particular, at feature sizes of less than 0.2 micrometer, on account of grain size problems within the metal-containing layer.

FIG. 2 shows a simplified plan view of a differently structured interconnect in accordance with a further prior art, as disclosed, for example, by the literature reference Q. T. Jiang et al., Proceedings of 2001 IITC conference, pages 227 to 229. According to this document, the structure-dependent recrystallization illustrated in FIG. 2 was recorded as a transitional phase, a metal-containing layer with different grain sizes 5′ and 5″ being formed in finely structured regions with, for example, a structure width w1 compared to coarsely structured regions with a structure width w2. In this case, the finely structured regions with a width w1, on account of their smaller grain size, have a significantly greater resistance than the coarsely structured regions, with their large grain sizes. However, a drawback of producing metal-containing thin films of this nature is a high level of outlay which is associated with the Damascene technology and a relatively high temperature and time demand which are required for annealing even in the finely structured regions, which may result in the electrical properties of the semiconductor components being adversely affected and in electromigration problems. In the finely structured regions, it is impossible to achieve the same grain sizes, even with a longer annealing time and a higher annealing temperature, as in the coarsely structured regions, since the maximum grain size is substantially limited by the geometry of the structures which are to be filled.

Therefore the invention is based on the object of providing a process for producing metal-containing thin films with a low electrical resistance which is easy and inexpensive to carry out. Furthermore, the invention is based on the object of producing metal-containing thin films with improved electromigration properties.

According to the invention, this object is achieved by measures described in Patent claim 1.

In particular as a result of the formation of a metal-containing layer with a first grain size up to a recrystallization thickness, followed by carrying out a recrystallization at this recrystallization thickness and final thinning of the metal-containing layer to a desired target thickness, sufficiently large grain sizes are achieved even at target thicknesses of well below 0.2 micrometer, so that it is possible to achieve both improved conductivities and electromigration properties.

To produce a structured metal-containing layer, in a further step the metal-containing thin film can be structured using conventional processes, with in particular an RIE process or a process using chlorine-based etching chemicals at a temperature of 180 to 300 degrees Celsius being used. In this way, it is possible to sufficiently finely structure even materials which are usually difficult to etch, such as copper, silver or if appropriate gold.

The recrystallization thickness is preferably set to a thickness of greater than 0.3 micrometer, with the result that recrystallization to sufficiently large grain sizes in the metal-containing layer is achieved in a particularly simple and rapid way.

Particularly for use in integrated semiconductor circuits, the substrate material may have a diffusion barrier layer, with the result that undesirable diffusion of substances from the metal-containing layer into the semiconductor components and in particular into an associated semiconductor substrate is reliably avoided and therefore the electrical properties of the semiconductor components remain unaffected.

Furthermore, the substrate material may have a very thin seed layer, with the result that in particular electrochemical deposition of the metal-containing layer is significantly simplified. However, in addition to an ECD process of this type, it is also possible to use conventional CVD or PVD processes. Furthermore, in addition to metals or alloys it is also possible to use doped metals, so that the electrical properties and/or recrystallization of the metal-containing layer can be improved further.

Particularly when electrochemically deposited metal-containing layers are being used, a recrystallization can be carried out by annealing at room temperature for a number of days, with the result that the effort and costs can be reduced significantly, and in particular the electrical properties in associated semiconductor components remain unaffected. Alternatively, however, it is also possible to carry out an anneal in a temperature range from 100 to 400 degrees Celsius and in a time range from 10 to 60 minutes, with the result that, furthermore, the electrical properties of the semiconductor components remain substantially unaffected and production is significantly accelerated.

In this context, it is preferable to carry out a recrystallization in a shielding-gas atmosphere using nitrogen, argon or in vacuo, with the result that undesirable oxidation of the metal-containing layer can be reliably prevented.

A target thickness is preferably set to a thickness of less than 0.1 micrometer, with the result that during subsequent structuring in particular electromagnetic or capacitive coupling problems between closely adjacent interconnects can be greatly reduced. In this way, a desirable aspect ratio AR or height:width ratio of less than 2 to 3 can be achieved even with very small feature sizes or interconnect widths.

The further subclaims characterize further advantageous configurations of the invention.

The invention is described in more detail below on the basis of an exemplary embodiment and with reference to the drawings, in which:

FIGS. 1a and 1b show simplified sectional views illustrating significant production steps involved in a conventional Damascene process;

FIG. 2 shows a simplified plan view for illustrating structure-related recrystallization properties in accordance with the prior art; and

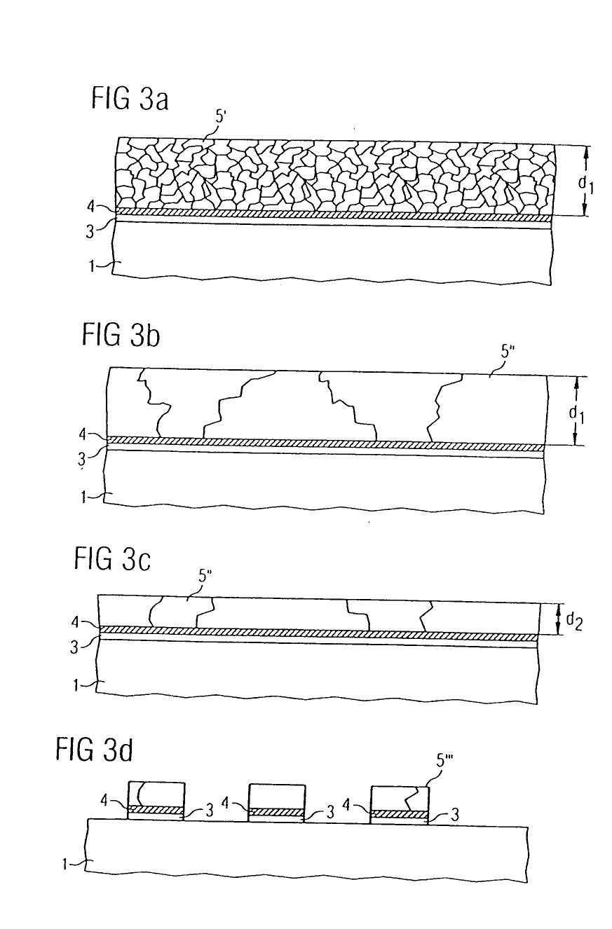

FIGS. 3a to 3d show simplified sectional views for illustrating significant process steps involved in the inventive production of metal-containing thin films.

The invention is described below on the basis of a Cu layer as metal-containing layer; other metal-containing layers, and in particular Al, Ag and/or Au, may also be used in the same way. Alternative materials of this type for the production of metallization layers are becoming increasingly important in particular in semiconductor technology, since they allow an improved conductivity and therefore faster cycle times and also a reduced power consumption to be achieved.

Particularly with very small feature sizes of less than 0.1 micrometer (with regard to their thickness or height), however, the problems described in the introduction result, with a significant increase in resistance occurring in particular on account of the very small grain sizes in the electrically conductive material. Furthermore, such small grain sizes lead to an increased but undesirable electromigration towards the respective interconnects. The benefits of these novel or alternative wiring materials may be reduced in this way.

The process according to the invention now demonstrates how it is possible, in a simple way, to produce metal-containing thin films with a low electrical resistance and improved electromigration properties which can be used even for very small feature sizes of <0.2 μm.

First of all, as shown in FIG. 3a, a diffusion barrier layer 3 is initially formed over the entire surface of a carrier substrate 1, which includes, for example, a semiconductor substrate with its associated elemental layers above it, in order to form, for example, a first metallization layer or wiring level. A diffusion barrier layer or liner 3 of this type consists, for example, of Ta, TaN, TiN, WN or similar materials, which reliably prevents undesirable diffusion of substances from a top layer into the semiconductor components or a semiconductor substrate of the carrier substrate 1 reliably. If diffusion of this nature does not cause any problems, a diffusion barrier layer 3 of this type may, of course, be dispensed with.

Furthermore, there is a seed layer 4, which consists, for example, of the same material as an actual metal-containing layer which is subsequently to be formed and essentially serves to allow simplified formation or deposition, located on the surface of the diffusion barrier layer 3. Both the diffusion barrier layer 3 and the seed layer 4 are formed, for example, by means of a PVD (physical vapour deposition) process or a CVD (chemical vapour deposition) process.

In the present exemplary embodiment, the seed layer 4 preferably consists of a Cu seed layer, with the result that a metal-containing Cu layer 5′ with a first grain size is formed on the substrate material 1 or the diffusion barrier layer and the seed layer 4 up to a recrystallization thickness d1 which is significantly thicker than desired. This formation of the metal-containing layer 5′ with its first, very small grain size can once again be carried out by means of a conventional PVD or CVD process, but it is then preferable to use an electrodeposition or electrochemical deposition process (ECD, electrochemical deposition). In this case, the seed layer 4 is used as an electrode for the metal-containing layer 5′ with its first grain size to grow on. The recrystallization thickness d1 is preferably set to a value of greater than 0.3 micrometer, with the result that a layer thickness which is sufficient for recrystallization is produced, in particular with copper being used. In the same way as the diffusion barrier layer 3, it is also possible in principle to dispense with the seed layer 4, but this means, however, that the growth conditions will be worse.

As an alternative to the above-described materials for the metal-containing layer, such as Cu, Al, Ag or Au, it is also possible to use alloys or doped metals, with the result that, depending on requirements, improved electrical properties or simplified production are achieved. Examples of doped metals of this type are AlCu with 0.5% of Cu, AlSiCu with 1% of Si and 0.5% of Cu, or CuTi, CuIn, CuSn, CuMg, CuAl, CuZr, etc.

Now, in accordance with FIG. 3b, in a subsequent step a recrystallization of the metal-containing layer 5′ with its first small grain size is carried out, in order to produce a metal-containing layer 5″ with a second grain size, which is larger than the first grain size, while the recrystallization thickness d1 remains unchanged.

On account of the unusually high layer thickness of this recrystallization thickness, recrystallization from the first (small) grain sizes to larger second grain sizes, corresponding to the recrystallization thickness d1, takes place even at room temperature and over a period of several days. Since the number of grain size boundaries is now reduced, the electrical conductivity of the metal-containing layer is significantly improved, and electromigration, which takes place substantially along these grain boundaries, is significantly reduced. Furthermore, during an annealing operation of this type at room temperature, there is no need for any additional equipment and there is no possibility of the electrical properties of semiconductor components located in the substrate material or carrier substrate 1 changing as a result of thermally induced outdiffusion.

Preferably, however, this annealing operation is carried out in a temperature range from 100 degrees Celsius to 400 degrees Celsius and over a period of 10 to 60 minutes, resulting in considerably accelerated production of these layers and in scarcely any deterioration in the electrical properties of, for example, existing semiconductor components. By way of example, an anneal of this type is carried out in a shielding-gas atmosphere comprising N₂, Ar or in a vacuum. However, it is also possible to establish alternative conditions in which oxidation of metal-containing layer is substantially prevented.

In accordance with FIG. 3c, in a subsequent process step the metal-containing layer 5″ with the second, i.e. larger grain size is thinned to a desired target thickness d2, preferably by carrying out chemical-mechanical polishing (CMP). Alternatively, however, it is also possible to carry out wet-etching processes, dry-etching processes and/or electropolishing processes, the metal-containing layer 5″ preferably being broken down again by electrochemical reactions in a liquid in the reverse way to the electrochemical deposition process.

The target thickness d2 can now be set to thicknesses of less than 0.2 micrometer and preferably to thicknesses of less than 0.1 micrometer, with the result that an extremely thin, planar Cu layer 5″ with extremely good electrical conductivity and greatly improved electromigration properties is obtained. This is because, as shown in FIG. 3c, the grain structures remain substantially unaffected by this thinning operation, so that a desired structure which is known as a bamboo structure is obtained in the metal-containing layer 5″. A grain-size structure of this type could not be achieved even if significantly higher annealing temperatures were used if a metal-containing layer of the target thickness d2 had simply been deposited at the outset.

Metal-containing thin films of this type with a thickness of less than 0.1 micrometer have advantages in particular during subsequent structuring, in that capacitive coupling between adjacent interconnects is significantly reduced. To achieve such a favourable lack of sensitivity to capacitive or electromagnetic couplings, it is usually necessary to have thickness/height ratios (aspect ratios) AR of less than 2 to at most 3, which in the case of very large scale integrated circuits leads to the required layer thicknesses being <0.1 μm.

FIG. 3d shows a final process step according to which the metal-containing thin film is optionally structured into desired interconnects or a structured metal-containing layer 5′″. Structuring of this type takes place, for example, by means of conventional RIE (reactive ion etching) processes, with, by way of example, photolithographic processes which are known and therefore not described previously having been carried out for masking purposes. Structuring using a wet-etching process is also possible in the case of relatively coarse structures.

Particularly if copper is used for the metal-containing layer, it is possible to use a from the literature reference Yan Ye et al., “Development of Cu etch process for advanced Cu interconnects”, Proceedings of 1998 IITC conference, pages 235 and 236, in which structuring using a chlorine-based etching chemical is carried out at a temperature of from 180 degrees to 300 degrees Celsius, and as a result the Cu layers which are relatively difficult to handle can be structured in a simple and clean way.

The invention has been described above on the basis of a Cu layer as the metal-containing layer, but it is not restricted to this option and in the same way also encompasses alternative metal-containing materials which have different recrystallization properties at different thicknesses. In the same way, the present invention is not restricted to a substrate material which includes a semiconductor circuit, but rather it may be formed in the same way on any other carrier substrates on which a very thin, electrically conductive layer with a low electrical resistance is to be formed. In the same way, the recrystallization thickness and the target thickness are only mentioned by way of example for a Cu layer; other materials may in principle require different thicknesses and in particular an alternative recrystallization thickness.

1-16. (Cancelled).

17. Process for producing metal-containing thin films with a low electrical resistance, comprising the steps of:
a) forming a metal containing layer (5′) with a first grain size up to a first thickness (d1) on the entire surface of a substrate material (1, 3, 4);
b) carrying out a recrystallization of the metal-containing layer (5′) which covers the entire surface to produce a metal containing layer (5″) with a second grain size, which is greater than the first grain size, which covers the entire surface at the first thickness (d1);
c) thinning the metal containing layer (5″) with the second grain size which covers the entire surface to produce a metal containing layer (5″) which covers the entire surface having a desired target thickness (d2); and
d) photolithographically structuring the metal-containing thinned layer (5″) with the second grain size which covers the entire layer to produce a structured metal containing layer (5′″).

18. Process according to claim 17, characterized in that in step a) the first thickness (d1) is set to a value of greater than 0.3 micrometer.

19. Process according to claim 18, characterized in that in step d) an RIE process is carried out.

20. Process according to claim 18, characterized in that in step d) a chlorine based etching chemical is used at a temperature of from 180 degrees Celsius to 300 degrees Celsius.

21. Process according to claim 18, characterized in that in step d) a wet chemical etch is used.

22. Process according to claim 17, characterized in that in step a) the substrate material has a diffusion barrier layer (3).

23. Process according to claim 17, characterized in that in step a) the substrate material has a seed layer (4).

24. Process according to claim 17, characterized in that in step d) the seed layer (4) and the diffusion barrier layer (3) are structured.

25. Process according to claim 17, characterized in that in step a) a CVD, PVD and/or ECD process is carried out.

26. Process according to claim 17, characterized in that in step a) Cu, Al, Ag and/or Au is used to form the metal-containing layer (5′) which covers the entire area.

27. Process according to claim 17, characterized in that in step a) doped metals are used to form the metal containing layer (5′) which covers the entire area.

28. Process according to claim 17, characterized in that in step b) an anneal is carried out at room temperature for several days.

29. Process according to claim 17, characterized in that in step b) an anneal is carried out in a temperature range from 100 degrees Celsius to 900 degrees Celsius over a period of 10 to 60 minutes.

30. Process according to claim 17, characterized in that in step b) the recrystallization is carried out in a shielding-gas atmosphere.

31. Process according to claim 17, characterized in that in step c) the target thickness (d2) is set to a value of less than 0.1 micrometer.

32. Process according to claim 17, characterized in that in step c) a CMP, dry etching, wet etching and/or electropolishing process is carried out.
